(19) United States
(12) Patent Application Publication
(10) Pub. No.: US 2004/0051550 A1
(43) Pub. Date: Mar. 18, 2004

(54) Semiconductor die isolation system

(76) Inventors: David Suitwai Ma, Cary, NC (US); George W. Alexander, Durham, NC (US); James J. Dietz, Durham, NC (US)

Correspondence Address: BRINKS HOFER GILSON & LIONE, P.O. BOX 10395, CHICAGO, IL, 60611, US

(21) Appl. No.: 10/243,363

(22) Filed: Sep. 12, 2002

(51) Int. Cl. G01R 31/26

(52) U.S. Cl. 324/765

(57) ABSTRACT

A semiconductor die isolation system electrically disconnects the semiconductor die from a routing mechanism when an isolation block is activated. The semiconductor die is tested through a routing mechanism connection with a testing device on a semiconductor wafer. The isolation block is activated when the testing is completed.

### RELATED APPLICATIONS

The following copending and commonly assigned U.S. patent applications have been filed on the same day as this application. All of these applications relate to and further describe other aspects of this application and are incorporated herein by reference in their entirety.

U.S. patent application Ser. No. ______, entitled “System and Method for Testing One or More Dies on a Semiconductor Wafer,” Attorney Reference Number 10808/63 2001 P 18014 US, filed on ______, and now U.S. Pat. No. ______.

U.S. patent application Ser. No. ______, entitled “Semiconductor Wafer Testing System,” Attorney Reference Number 10808/75 2001 P 18015 US, filed on ______, and now U.S. Pat. No. ______.

### FIELD

This invention generally relates to semiconductor wafer testing methods and devices. More particularly, this invention relates to semiconductor die testing systems with circuitry and routing mechanism in the kerf area of a semiconductor wafer.

### BACKGROUND

Integrated circuits typically begin fabrication as a die on a flat, circular substrate or wafer. The die comprises a rectangular portion of the wafer surface and is also known as a chip, circuit, or the like. Each wafer usually is segmented by scribe or saw lines into multiple dies, which typically form essentially identical rectangular circuit patterns. Some dies may be engineering or test dies. Other dies may be edge dies where the wafer does not permit the formation of a complete die along the edge of the wafer. On many wafers, there is a kerf area or area between the dies. The size of the kerf area varies as the number and arrangement of the dies on the wafer varies. When fabrication is completed, the wafer is cut along the kerf area to separate the dies for use in IC devices.

Dies are tested after fabrication to determine whether a suitable IC has been manufactured. The dies may be individually tested after separation of the wafer. The dies also may be serially tested before separation of the wafer. Die testing usually involves the use of mechanical probes from a testing device. The mechanical probes engage test pads or pins on the die. Once engaged, the testing device applies input signals or voltages to the die, and then receives output signals or voltages from the die.

Many semiconductor wafers are manufactured with circuitry and/or routing mechanisms in the kerf area for testing the dies. The routing mechanism typically is a metal or other conductive channel layered onto the semiconductor wafer. The routing mechanism may have a micro wire configuration or similar shape and makes an electrical connection for passing signals and/or voltages between the dies, test circuitry, and testing device.

Each die usually has a test pad that is connected to the circuitry and/or testing device via the routing mechanism. When fabrication of the semiconductor wafer is completed, the routing mechanism typically is cut when the wafer is cut along the saw lines. A portion of the routing mechanism usually remains connected to the test pad. This routing mechanism portion may cause operating problems when the die is used as an IC. The routing mechanism portion can act like antenna, “picking up” signals and energy that may interfere with operation of the die. The routing mechanism portion may create transmission line effects such as reflective noise when signals or voltage pass through the die.

### SUMMARY

This invention provides a semiconductor die isolation system that electrically disconnects the semiconductor die from a routing mechanism when an isolation block is activated. The routing mechanism may be used for testing the semiconductor die when fabrication is completed and at other times.

The semiconductor die isolation system may have a semiconductor die, an isolation block, and a routing mechanism. The isolation block is connected to the semiconductor die. The routing mechanism is connected to the isolation block. The semiconductor die is electrically disconnected from the routing mechanism when the isolation block is activated.

In one method for isolating a semiconductor line, a routing mechanism is electrically disconnected from a semiconductor die when an isolation block is activated. In another method for isolating a semiconductor die, a semiconductor die is tested through a routing mechanism. An isolation block is activated when testing is completed.

Other systems, methods, features, and advantages of the invention will be or will become apparent to one skilled in the art upon examination of the following figures and detailed description. All such additional systems, methods, features, and advantages are intended to be included within this description, within the scope of the invention, and protected by the accompanying claims.

### BRIEF DESCRIPTION OF THE FIGURES

The invention may be better understood with reference to the following figures and detailed description. The components in the figures are not necessarily to scale, emphasis being placed upon illustrating the principles of the invention. Moreover, like reference numerals in the figures designate corresponding parts throughout the different views.

FIG. 1 is a block diagram of a semiconductor die isolation system according to one embodiment.

FIG. 2 is a block diagram of a semiconductor die isolation system according to another embodiment.

FIG. 3 is a flowchart of a method of one embodiment for isolating a semiconductor die.

### DETAILED DESCRIPTION OF THE PREFERRED EMBODIMENTS

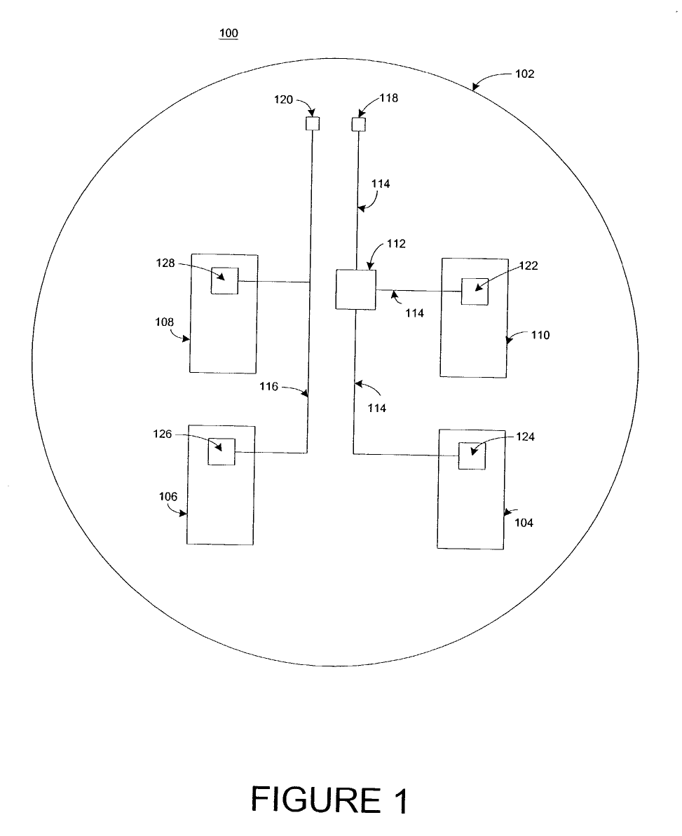

FIG. 1 is a block diagram of a semiconductor die isolation system 100 according to an embodiment. The semiconductor die isolation system 100 includes a semiconductor wafer 102, dies 104, 106, 108, and 110, test circuitry 112, routing mechanisms 114 and 116, wafer test pads 118 and 120, and die test pads 122, 124, 126, and 128. The dies 104, 106, 108, and 110 and other components are formed on the semiconductor wafer using a photolithographic or a similar process for manufacturing an integrated circuit (IC).

Each die 104, 106, 108, and 110 has a corresponding die test pad 122, 124, 126, and 128 for receiving and transmitting signals and/or voltages with a testing device (not shown). Dies 104 and 110 are connected to wafer test pad 118 via test circuitry 112 and routing mechanism 114. Dies 106 and 108 are connected to wafer test pad 120 via routing mechanism 116. During testing, the wafer test pads 118 and 120 are connected to test pins (not shown) from a testing device (not shown). The test circuitry 112, wafer test pads 118 and 120, and part of the routing mechanisms 114 and 116 are in the kerf area of the semiconductor wafer 102. The kerf area is an area adjacent to the dies that is cut away when the dies are separated. The test circuitry 112, wafer test pads 118 and 120, and part of the routing mechanism may be in another area of the semiconductor wafer 102 such as an edge die (where a complete die cannot be formed at an edge), a test die (a die location not used to manufacture a die), and the like.

While particular configurations and components are shown, the isolation system 100 may have other configurations including those with fewer or additional components. The isolation system 100 may have one die or other multiples of dies including several hundreds of dies and even more. All or a portion of the dies may be connected directly to one or more of the wafer test pads. All or a portion of the dies may be connected indirectly to one or more of the wafer test pads through one or more test circuits. One or more of the wafer test pads may be disposed on one or more of the dies in lieu of the die test pad. Each die may have multiple die test pads. Other arrangements of the components on the semiconductor wafer may be used.

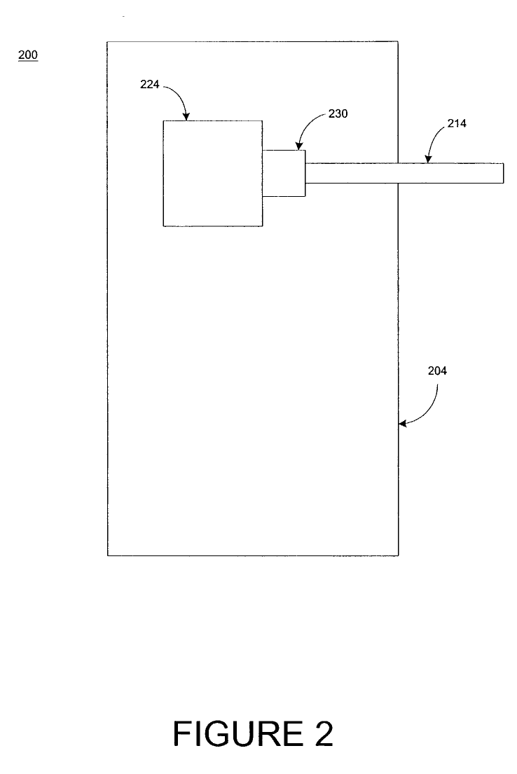

FIG. 2 is a block diagram of a semiconductor die isolation system 200 according to another embodiment. The semiconductor die isolation system 200 includes a die 204 formed on a semiconductor wafer (not shown). The die 204 has a die test pad 224, which is connected to a routing mechanism 214 through an isolation block 230. The die testing pad 224 may be part of or integrated with the die 204. The isolation block 230 also may connect directly the die 204 without the die testing pad 224, in which case the isolation block 230 would operate as discussed below to electrically disconnect the die 204 from the routing mechanism 214. The routing mechanism 214 connects directly to a wafer test pad (not shown) or indirectly to the wafer test pad through test circuitry (not shown).

When activated, the isolation block 230 electrically disconnects the die test pad 224, and hence the die 204, from the routing mechanism 214. The isolation block may be activated by a control signal or voltage from the testing device. The isolation block may be activated by a signal or voltage from another device such as another testing device or the die. Electrically disconnects includes electrical, magnetic, and physical separation, a combination, and other separation techniques. The electrical disconnection reduces or eliminates the die operating problems associated with the routing mechanism. The isolation block 230 may be a fuse, circuit breaker, switch, transistor, or similar device that physically separates the die test pad 224 from the routing mechanism 214. The isolation block 230 may be electrical circuitry or a similar mechanism that electrically and/or magnetically separates the die test pad 224 from the routing mechanism 214. The electrical circuitry may dampen, ground, resist, isolate, divert, or otherwise prevent the routing mechanism for electrically interfering with operation of the die. The electrical disconnection may be a temporary or permanent. Permanent separation indicates the die test pad 224 and routing mechanism 214 cannot be reconnected through the isolation block 230. Temporary separation indicates the die test pad 224 and routing mechanism can be reconnected through the isolation block 230.

In operation, the dies on the semiconductor wafer are connected to a testing device (not shown) after fabrication is completed. The semiconductor wafer also may be connected during fabrication for interim testing if permitted by the semiconductor wafer design and the manufacturing process. During testing, the testing device passes and receives signals and/or voltages from the dies.

The isolation block 230 is activated when testing is completed and prior to separation of the dies from each other. A testing device may be used to activate the isolation block 230 when testing is completed. Another testing device may be connected to the semiconductor wafer for activation of the isolation block 230. The isolation block 230 also may be activated after the dies are separated from each other. The testing device or another testing device is connected to the die test pad, the remaining portion of the routing mechanism, or another part of the die to activate the isolation block 230.

When the isolation block 230 is temporarily activated, the isolation block 230 may be subsequently deactivated to permit additional testing of the die. Alternatively, the isolation block may be kept in an activated state and then deactivated prior to testing. The isolation block 230 also may have a delay activation. The activation may occur a predetermined time period after testing is completed or after another event. The delay activation may occur after testing is completed multiple of times. The activation also may occur as part of a startup procedure when the die is first placed into operation as an integrated circuit.

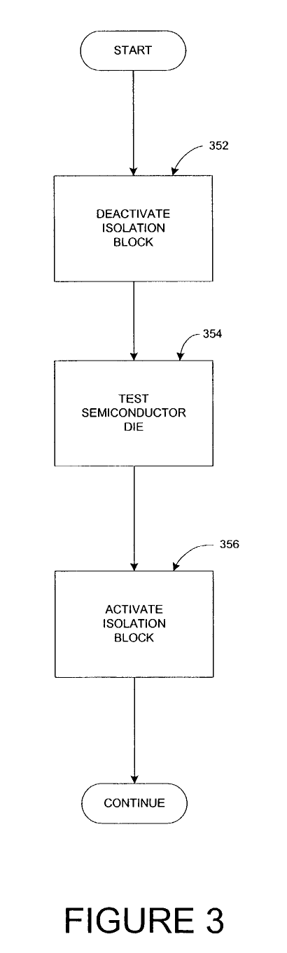

FIG. 3 is a flowchart of a method for isolating a semiconductor die. An isolation block on the semiconductor die is deactivated 352. When deactivated, an electrical connection occurs between a die testing pad, and hence the die, and a routing mechanism on the die. The isolation block may have been manufactured in a deactivated state or may have been deactivated in a previous mode of operation or testing. The isolation block also may have been manufactured in an activated state or may have been activated in a previous mode of operation or testing.

While the isolation block is deactivated, the die is tested 354 by a testing device connected to the die via the routing mechanism. The die receives and passes test signals or voltages from the routing mechanism through the isolation block and die test pad. The routing mechanism may connect directly to a wafer test pad on the semiconductor wafer or may connect indirectly to the wafer test pad through test circuitry. The testing device is connected to the wafer test pad to test the die.

When testing is completed, the isolation block is activated 356. The die testing pad, and hence, the die, are electrically disconnected from the routing mechanism. The electrical disconnection may be temporary or permanent as previously discussed. When the electrical disconnection is temporary, the isolation block may be subsequently deactivated for additional testing.

Various embodiments of the invention have been described and illustrated. However, the description and illustrations are by way of example only. Other embodiments and implementations are possible within the scope of this invention and will be apparent to those of ordinary skill in the art. Therefore, the invention is not limited to the specific details, representative embodiments, and illustrated examples in this description. Accordingly, the invention is not to be restricted except in light as necessitated by the accompanying claims and their equivalents.

What is claimed is:

1. A semiconductor die isolation system, comprising:
a semiconductor die;
an isolation block connected to the semiconductor die; and
a routing mechanism connected to the isolation block;
where the semiconductor die is electrically disconnected from the routing mechanism when the isolation block is activated.

2. The semiconductor die isolation system according to claim 1, further comprising a die test pad connected to the semiconductor die and the isolation block, where the die test pad is electrically disconnected from the routing mechanism when the isolation block is activated.

3. The semiconductor die isolation system according to claim 1, where the semiconductor die comprises an integrated circuit.

4. The semiconductor die isolation system according to claim 1, where the isolation block comprises a fuse.

5. The semiconductor die isolation system according to claim 1, where the isolation block comprises an electrical circuit.

6. The semiconductor die isolation system according to claim 1, where the semiconductor die is disconnected permanently from the routing mechanism.

7. The semiconductor die isolation system according to claim 1, where the semiconductor die is disconnected temporarily from the routing mechanism.

8. The semiconductor die isolation system according to claim 1, further comprising:
a semiconductor wafer; and
a wafer test pad connected to the semiconductor wafer;
where the routing mechanism is connected to the wafer test pad.

9. The semiconductor die isolation system according to claim 8, further comprising test circuitry connected to the routing mechanism and to the wafer test pad.

10. The semiconductor die isolation system according to claim 8, where the isolation block is activated by a control signal from a testing device.

11. The semiconductor die isolation system according to claim 8, further comprising a plurality of semiconductor dies formed on the semiconductor wafer, where each semiconductor die has an isolation block connected to a routing mechanism, and where each semiconductor die is electrically disconnected from the routing mechanism when each isolation block is activated.

12. A method for isolating a semiconductor die, the semiconductor die having an isolation block connected to a routing mechanism, comprising electrically disconnecting the semiconductor die from the routing mechanism when the isolation block is activated.

13. The method of isolating a semiconductor die according to claim 12, further comprising:
electrically connecting the isolation block to the routing mechanism when the isolation block is deactivated; and
testing the semiconductor die through the routing mechanism.

14. The method for isolating a semiconductor die according to claim 12, further comprising testing the semiconductor die through the routing mechanism prior to electrically disconnecting the semiconductor die from the routing mechanism.

15. The method for isolating a semiconductor die according to claim 12, further comprising activating the isolation block in response to a control signal.

16. The method for isolating a semiconductor die according to claim 15, where a testing device provides the control signal.

17. A method for isolating a semiconductor die having an isolation block connected to a routing mechanism, comprising:
testing the semiconductor die through the routing mechanism; and
activating the isolation block when testing is completed.

18. The method for isolating a semiconductor die according to claim 17 further comprising deactivating the isolation block.

19. The method for isolating a semiconductor die according to claim 18, where the isolation block is deactivated prior to testing the semiconductor die.
